(19) United States
(12) Patent Application Publication
(10) Pub. No.: US 2003/0230776 A1
(43) Pub. Date: Dec. 18, 2003

(54) System on chip

(76) Inventors: Chien-Hung Liu, Taipei City (TW); Shyi-Shuh Pan, Kao-Hsiung City (TW); Shou-Wei Huang, Chi-Lung City (TW); Erh-Kun Lai, Tai-Chung Hsien (TW); Ying-Tso Chen, Kao-Hsiung Hsien (TW)

Correspondence Address: NAIPO (NORTH AMERICA INTERNATIONAL PATENT OFFICE), P.O. BOX 506, MERRIFIELD, VA, 22116, US

(21) Appl. No.: 10/064,122

(22) Filed: Jun. 12, 2002

(51) Int. Cl. H01L 29/76

(52) U.S. Cl. 257/319

(57) ABSTRACT

A system on chip (SOC) characterized by nitride read only memory (NROM) and read only memory (ROM) has a P-type substrate, and at least an NROM area and a read only memory area defined on the surface of the substrate. ONO layers are disposed along a first direction and positioned in the NROM area and the read only memory area. A bit line is positioned in the substrate between each ONO layer. Oxide layers are positioned atop each bit line. A plurality of word lines disposed along a second direction covers each ONO layer in the NROM area and the read only memory area, so as to form a plurality of NROM cells at the intersection of the NROM area and each ONO layer, and to form a plurality of read only memory cells at the intersection of the read only memory area and each ONO layer. A doping area is optionally positioned at a bottom side of a read only memory cell, so as to cause the read only memory cell to have at least two different threshold voltages and to form ROM code.

### BACKGROUND OF INVENTION

1. Field of the Invention

The present invention relates to a system on chip(SOC), and more particularly, to a system on chip characterized by utilizing nitride read only memory(NROM) and read only memory(ROM), and being formed of nitride read only memory.

2. Description of the Prior Art

Read only memory (ROM) devices are semiconductor devices used for data storage. A ROM is composed of a plurality of memory cells, and is widely applied in data storage and memory systems of computers today. Read only memory can be classified into mask ROM, programmable ROM (PROM), erasable programmable ROM (EPROM), electrically erasable programmable ROM (EEPROM), nitride read only memory (NROM) categorized as EEPROM, and flash ROM, according to data storage methods utilized by the types of ROM. A feature of read only memory is that once data or information is stored, the data will not disappear upon an interruption of power. Therefore, read only memory is also called non-volatile memory.

In the modern electronics industry, read only memory and non-volatile memory exist in various products. When read only memory and electrically erasable programmable ROM exist together, greater effectiveness is produced. For example, when this combination is applied in a circuit design of a mobile phone, read only memory in the mobile phone is used for storing information like menus, and electrically erasable programmable ROM is used to store information like address books. If the two ROM types are simultaneously fabricated on a single chip, not only is less room occupied, but there is also a lower cost involved than if the two devices are fabricated on two separate chips. Therefore, if a standard process for manufacturing a specific kind of memory device can be utilized, by adding some simple steps, to achieve an objective of fabricating a single chip comprising both read only memory and non-volatile ROM, the above mentioned problems can be resolved. Also, as the updated electronics industry is moving more and more toward systems on chip(SOC), if a control circuit can be integrated in a single chip comprising read only memory and non-volatile ROM, further progress will be made.

Flash ROM, which uses non-volatile memory, usually utilizes a floating gate composed of polysilicon and metal for storing charges, therefore an extra gate exists aside from a typical control gate. Please refer to FIG. 1(a) and FIG. 1(b). FIG. 1(a) and FIG. 1(b) are schematic diagrams of writing and erasing of a flash ROM cell 10. As shown in FIG. 1, the flash ROM cell 10 is fabricated on a semiconductor substrate 12. The flash ROM 10 comprises a floating gate 14 and a control gate 16. Two N-type doping areas 18 are set in the semiconductor substrate 12 at two sides of the floating gate 14 and the control gate 16, and a channel 22 is defined between the two N-type doping areas 18.

When writing to the cell, hot electrons tunnel through a thin silicon dioxide layer (not shown) beneath the floating gate 14, enter the floating gate 14, and are trapped in the floating gate 14. Storing negative charges in the floating gate 14 represents storing a data “1” in the flash ROM cell 10, as opposed to storing a “0”. To electrically erase a memory state of the flash ROM cell 10, adequate negative voltage must be applied to the control gate 16 of the flash ROM cell 10. The electrons trapped in the floating gate 14 tunnel through the thin silicon dioxide layer (not shown) beneath the floating gate 14 again, and escape from the floating gate 14, so the data stored in the flash ROM cell 10 is erased, the state prior to storing information is recovered, and new information can be written into the flash ROM cell 10.

In U.S. Pat. No. 5,403,764, Yamamoto et al. proposes a flash memory chip comprising read only memory. In other words, a portion of memory cells in the flash memory chip are written with so called ROM code by way of an ion implantation method, completed with the writing procedure, and become read only memory.

Please refer to FIG. 2. FIG. 2 is a sectional view of a flash ROM chip 30 comprising read only memory, according to the prior art. As shown in FIG. 2, the flash ROM chip 30 comprising read only memory according to the prior art is made on a P-type silicon substrate 32. A surface of the P-type silicon substrate 32 is divided into a flash ROM area 34 and a read only memory area 36. The flash ROM area 34 comprises a flash ROM cell 35. The read only memory 36 comprises a first read only memory device 37 and a second read only memory device 38. Each device is isolated by a field oxide layer (FOX) 39.

The channels in the first read only memory device 37 and the second read only memory device 38 comprise a first P+ doping area 41 and a second P+ doping area 42, respectively. The first P+ doping area 41 and the second P+ doping area 42 are formed by way of ion implantation. The first P+ doping area 41 is a boron ion doping area with an ion concentration ranging between 10¹⁶ to 10¹⁷ dopants/cm³. The second P+ doping area 42 is a boron ion doping area with an ion concentration ranging between 10¹⁷ to 10¹⁸ dopants/cm³. The first P+ doping area 41 is utilized for adjusting a threshold voltage (Vth) of the first read only memory device 37 in the read only memory area 36 to a first specific value, so the threshold voltage of the first read only memory 37 is adjusted to approximately 1V, and stores a “1” bit. The second P+ doping area 42 is utilized for adjusting a threshold voltage (V_{TH}) of the second read only memory device 38 in the read only memory area 36 to a second specific value, so the threshold voltage of the second read only memory 38 is adjusted to approximately 7V, and stores a “0” bit.

A very thin first isolation layer 44 is positioned on the surface of the P-type silicon substrate 32. The surface of the first isolation layer 44 further comprises a first read only memory gate 54, a second read only memory gate 56 and a flash ROM gate 58 composed of a first polysilicon layer 46, an inter-layer isolation 48, and a second polysilicon layer 52. In the double gate structure, the first polysilicon layer 46 is used as a “floating gate,” the second polysilicon layer 52 is used as a “control gate,” and the inter-layer isolation 48 is composed of silicon nitride or silicon oxide. Although the gates of the first and the second read only memory devices 37,38 only require single layer structure, the double gates structure is not restricted to a three layer structure. However, in this prior art method, all of the gates are formed in the same process step in order to reduce a number of process steps.

The two sides of the double gate 54,56 of the first and the second read only memory devices 37, 38, respectively, comprise an N+ type source 62 and an N+ type drain 64. The source 62 and the drain 64 are formed by way of a phosphorous ion implantation process. A source 66 and a drain 68 of N+ type are positioned at the two sides of the double gate 58 of the flash ROM cell 35, respectively. The source 66 and the drain 68 are formed by way of another phosphorous ion implantation process. Therefore, under the premise of sharing the flash ROM structure, only two P+ doping areas 41,42 need to be added in the flash ROM structure in order to adjust the threshold voltage of the device. The first and the second read only memory 37,38 in the read only memory area 36 on the flash ROM chip 30 area are written with “1” bit or “0” bit.

However, the flash ROM chip in the prior art only comprises a portion of read only memory, so the objective of having a system on chip is not achieved. Moreover, the gate of the flash ROM is a three layered structure, floating gate—inter-layer dielectric—control gate. Whenever the device needs to fulfill electrical properties requirements, quality of the three layered structure is very important and usually requires adequate processing. The manufacturing process is more complex and the cost is higher, which makes the process unsuitable for manufacturing a system on chip. Therefore, to develop and manufacture a system on chip which utilizes memory devices with a lower cost and comprises both read only memory and other non-volatile memory, the electrical writing step after completion required by typical non-volatile memory being omitted, becomes a very important subject.

### SUMMARY OF INVENTION

It is therefore a primary objective of the present invention to provide a system on chip(SOC), and more particularly, to a system on chip characterized by nitride read only memory(NROM) and read only memory(ROM) formed in nitride read only memory.

In a first preferred embodiment of the present invention, the system on chip comprises a P-type substrate, at least a nitride read only memory and a read only memory area defined on a surface of the substrate, a plurality of ONO layers disposed along a first direction in the nitride read only memory area and the read only memory area. A bit line is positioned in the substrate between each ONO layer, and a plurality of oxide layers is positioned atop each bit line. A plurality of word lines disposed along a second direction covers each ONO layer in the nitride read only memory area and the read only memory area, and forms a plurality of nitride read only memory cells at an intersection of each ONO layer in the nitride read only memory area, and a plurality of read only memory cells at an intersection of each ONO layer in the read only memory area. A doping area is optionally positioned at a bottom of a read only memory cell in order to cause the read only memory to have at least two different threshold voltages, and to form ROM code.

It is an advantage of the present invention to add a p-type dopant implantation area into the nitride read only memory structure, so as to make both the read only memory and other non-volatile memory on a system on chip. Therefore, the time and manpower exhausted by electrical writing, which leads to infeasibility of mass production, generally required after completing the non-volatile memory is avoided. Because the manufacturing process of nitride read only memory is simple, the cost of NROM is similar to the cost of mask ROM, and functionality of the chip is comparable to functionality of flash ROM, making the system on chip comprising read only memory and other non-volatile memory made of nitride read only memory reduces costs and simplifies processing. Furthermore, the goal of making a system on chip can be achieved.

These and other objectives of the present invention will no doubt become obvious to those of ordinary skill in the art after having read the following detailed description of the preferred embodiment that is illustrated in the various figures and drawings.

### BRIEF DESCRIPTION OF DRAWINGS

FIG. 1(a) and FIG. 1(b) are schematic diagrams of writing and erasing of the flash ROM cell.

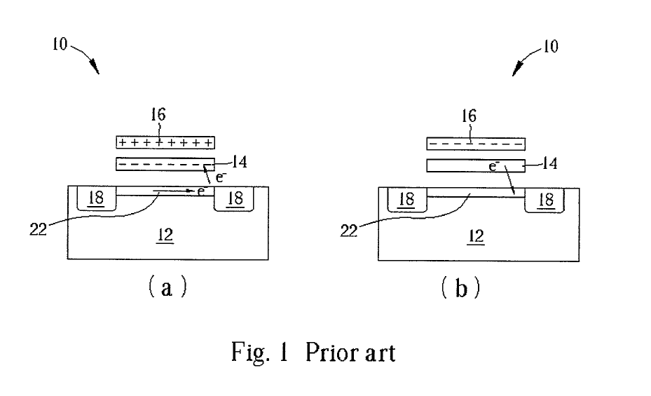

FIG. 2 is a sectional view of a flash ROM chip comprising read only memory according to the prior art.

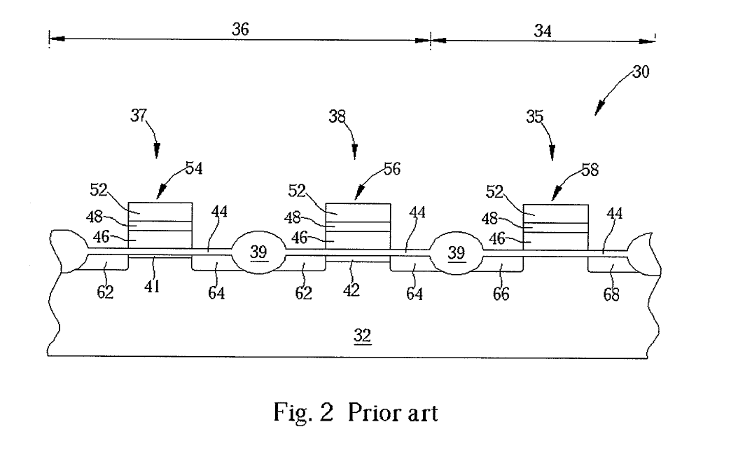

FIG. 3 is a schematic diagram of writing of a nitride read only memory cell.

FIG. 4 is a sectional view of a system on chip characterized by nitride read only memory and read only memory, formed of nitride read only memory according to the present invention.

### DETAILED DESCRIPTION

Nitride read only memory (NROM) is a kind of non-volatile memory, the primary feature of which is to utilize an isolating dielectric layer composed of silicon nitride as a charge trapping medium. Since the silicon nitride layer is highly dense, hot electrons tunneling through a MOS transistor into the silicon nitride layer are trapped in the silicon nitride layer, which further forms a non-uniform concentration distribution to improve a reading velocity, and avoid leakage current. Therefore, a floating gate is not required to achieve the same goal.

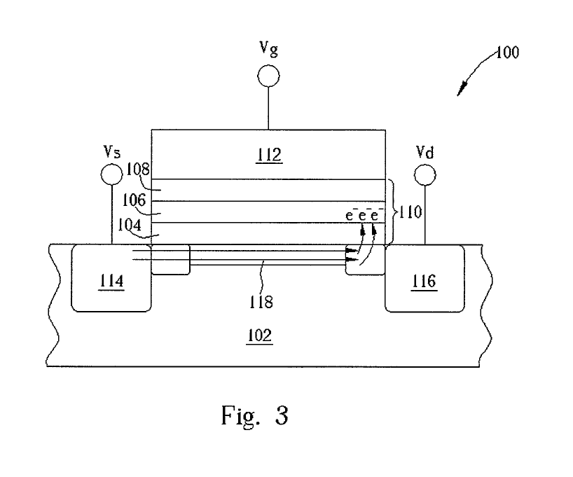

Please refer to FIG. 3. FIG. 3 is a schematic diagram of writing of the nitride read only memory cell 100. As shown in FIG. 3, the nitride read only memory cell 100 is made on a semiconductor substrate 102. The nitride read only memory cell 100 comprises an ONO dielectric layer 110 composed of a bottom oxide layer 104, a silicon nitride layer 106 and a top oxide layer 108. A gate 112 is positioned atop the ONO dielectric layer 110, a source 114 and a drain 116 are positioned in the semiconductor substrate 102 at the two sides of the gate 112, and a channel 118 is defined between the source 114 and the drain 116.

To write data, hot electrons are accelerated and tunnel through the bottom oxide layer 104, and are trapped in the silicon nitride layer 106 near the drain. An action of storing negative charges in the silicon nitride layer 106 near the drain 116 is writing. To erase information written into the nitride read only memory cell 100, adequate negative voltage must be applied to the gate 112 of the nitride read only memory cell 100 and adequate positive voltage must be applied to the drain 116 of the nitride read only memory cell 100. Hot holes are therefore generated and tunneling through the bottom oxide layer 104 due to the attraction of the negative voltage applied to the gate 112. As a result, they enter the silicon nitride layer 106 to neutralize the electrons trapped in the silicon nitride layer 106. The information written into the nitride read only memory 100 is erased, the state prior to information storing is recovered, and writing of new information can be performed.

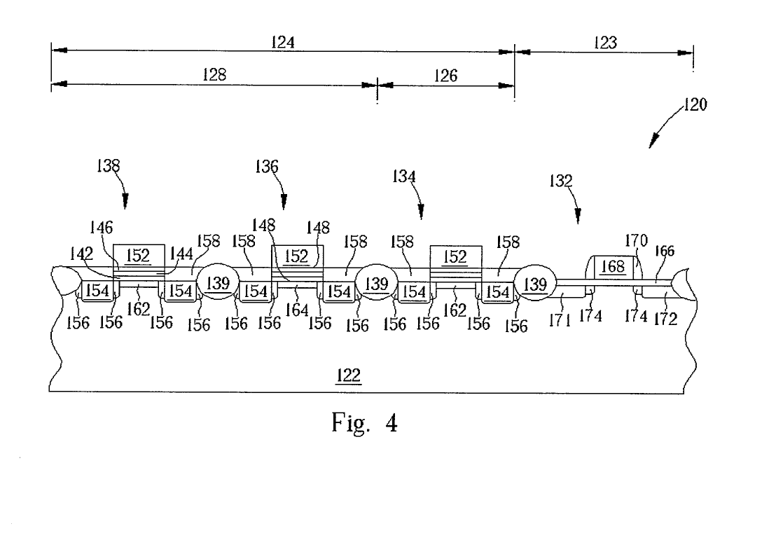

Please refer to FIG. 4. FIG. 4 is a sectional view of a system on chip 120 characterized by non-volatile memory and read only memory, and formed of nitride read only memory 134. As shown in FIG. 4, the system on chip 120 according to the present invention is made on a P-type silicon substrate 122. A surface of the system on chip 120 comprises a periphery area 123 and a memory area 124. The memory area 124 comprises a non-volatile memory area 126 and a read only memory area 128. The periphery area 123 comprises a periphery transistor 132. The non-volatile memory area 126 is mainly used for fabricating the nitride read only memory 134. The read only memory area 128 comprises a high threshold voltage read only memory 136 and a low threshold voltage read only memory 138. Field oxide layers (FOX) 139 isolate each device. Please note that generally speaking, read only memory is a kind of non-volatile memory, however for the convenience of illustration, the non-volatile memory area 126, mentioned in the detailed description of the present invention, is for fabricating a plurality of nitride read only memory cells 134.

The surfaces of the high threshold voltage read only memory 136 and the low threshold voltage read only memory 138 in the read only memory area, and the surface of the nitride read only memory 134 in the non-volatile memory area, on the P type silicon substrate 122, each comprise an ONO dielectric layer 148 composed of a bottom oxide layer 142, a silicon nitride layer 144 and a top oxide layer 146. Gates 152 of the high threshold voltage read only memory 136 and the low threshold voltage read only memory 138 in the read only memory area, and the gate 152 of the nitride read only memory 134 in the non-volatile memory area, overlay the ONO dielectric layers 148, respectively. The gate 152 is composed of a polysilicon layer or polysilicide on the surface of the polysilicon layer. And, the gate 152 is a portion of word line (not shown). The ONO dielectric layers 148 of the high threshold voltage read only memory 136 and the low threshold voltage read only memory 138 in the memory area are used as gate dielectric layers of the high threshold voltage read only memory 136 and the low threshold voltage read only memory 138. Therefore, the ONO dielectric layer 148 of the high threshold voltage read only memory 136 and the low threshold voltage read only memory 138 can replace a silicon oxide layer.

The P type silicon substrate 122 comprises bit lines 154 at two sides of the gates 152. The bit lines 154 are made by way of an arsenic ion implantation process with a dosageranging from 2˜4 E15/cm² and an energy approximately 50 KeV. The two sides of each bit line 154 each comprise a pocket ion implantation area 156. The pocket ion implantation areas 156 are formed by way of two angled ion implantation processes with dosages ranging from 1E13 to 1E15 ions/cm² and, energies ranging from 20 to 150 KeV and 20°˜45° incident angles to the P type silicon substrate 122. A thermal oxide layer 158 is positioned atop each bit line 154. The objective in making the pocket ion implantation areas 156 is to provide a high electric field area at one side of the channel, to enhance the hot carrier effect, which increases a velocity of electrons passing through the channel during programming. In other words, the electrons are accelerated, so that more electrons can acquire enough dynamic energy through collision or scattering effect and pass the bottom oxide layer 142, and enter the silicon nitride layer 144, in order to improve a writing efficiency.

A channel 162 is defined between two neighboring bit lines 154. A P-type dopant implantation area 164 is positioned in the channel 162 of the high threshold voltage read only memory 136. The P-type dopant implantation area 164 is formed by way of an ion implantation process, and the ion implantation process is also called a ROM code implantation process. Since the P-type dopant implantation area 164 is positioned in the channel 162, the threshold voltage for the high threshold voltage device 136 in the read only memory area 128 is lifted to a specific value. And, the threshold voltage for the high threshold voltage device 136 is different from the low threshold voltage device 138 in the read only memory area 128, so that different information can be simultaneously stored. Therefore when the system on chip 120 is operating, 0&1 or 1&0 can be represented, respectively.

Moreover, a gate oxide layer 166 positioned on the surface of the P-type silicon substrate 122 is set in the periphery transistor 132 in the periphery area 123 on the system on chip 120. A gate 168 is positioned on the gate oxide layer 166, and spacers 170 are positioned at the two sides of each gate 168. A source 171 and a drain 172 are positioned in the P-type silicon substrate 122 at the two sides of each gate 168, and a lightly doped drain (LDD) 174 is positioned in the P-type silicon substrate 122 at the two sides of each gate 168, respectively. Please note that the composition of the gate 168 is the same as the composition of the gate 152 in the memory area 124. Therefore, the gates can be completed in the same process. Also, the ONO dielectric layer 148 can exist in the whole memory area 124, or only exist in the nitride read only memory 134 in the memory area 124. If the ONO dielectric layer 148 only exists in the nitride read only memory 134 in the memory area 124, a gate oxide layer with the same composition as that of the gate oxide layer 166 replaces the ONO dielectric layer 148 in the read only memory area 128. Of course the gate oxide layer can be completed in the same process step as the gate oxide layer 166 in the periphery area 123.

Aside from the above mentioned transistor structures and memory cell structure, the system on chip 120 further comprises an inter-metal dielectric layer (ILD) structure (not shown), a metal layer structure (not shown), a contact hole structure (not shown) and a contact plug structure (not shown). These structures electrically connect the transistor structures and the memory structures on the system on chip 120, according to the circuit design, and form a system on chip 120 which can work independently and cooperate with other systems on chip. With an exception of the periphery circuit comprising periphery transistors, the system on chip 120 comprises the read only memory and the non-volatile memory, and all of the non-volatile memory cells are nitride read only memory cells 134.

The system on chip provided by the present invention utilizes the nitride read only memory structure and the added P-type dopant implantation area to allow the read only memory and other non-volatile memory to exist simultaneously in a single system on chip. Therefore, the time and manpower exhausted by electrical writing, which leads to infeasibility of mass production, generally required after completing the non-volatile memory is avoided. Because the manufacturing process of nitride read only memory is simple, the cost of NROM is similar to the cost of mask ROM, and functionality of the chip is comparable to functionality of flash ROM, making the system on chip comprising read only memory and other non-volatile memory made of nitride read only memory reduces costs and simplifies processing. Furthermore, the goal of making a system on chip can be achieved.

Compared to the prior art method of forming the flash ROM chip comprising read only memory, the present invention utilizes the nitride read only memory and added P-type dopant implantation process to make the system on chip characterized by read only memory and other non-volatile memory. Therefore, the time and manpower exhausted by electrical writing, which leads to infeasibility of mass production, generally required after completing the non-volatile memory is avoided. Because the manufacturing process of nitride read only memory is simple, the cost of NROM is similar to the cost of mask ROM, and functionality of the chip is comparable to functionality of flash ROM, making the system on chip comprising read only memory and other non-volatile memory made of nitride read only memory reduces costs and simplifies processing. Furthermore, the goal of making a system on chip can be achieved.

Those skilled in the art will readily observe that numerous modifications and alterations of the device may be made while retaining the teachings of the invention. Accordingly, the above disclosure should be construed as limited only by the metes and bounds of the appended claims.

What is claimed is:

1. A system on chip (SOC) characterized by nitride read only memory (NROM) and read only memory (ROM), the system comprising:
a substrate of a first conductive type, a nitride read only memory (NROM) area, a read only memory area and a periphery area defined on a surface of the substrate;
a plurality of ONO (oxide-nitride-oxide) layers disposed along a first direction in the nitride read only memory area and the read only memory area, a conductive doping area with a second conductive type positioned in the substrate between each ONO layer and used as bit lines of the system on chip;
an oxide layer positioned atop each bit line;
a plurality of word lines covering each ONO layer in the nitride read only memory and the read only memory, the word lines disposed along a second direction and forming a nitride read only memory cell at the intersection of each ONO layer in the nitride read only memory area, and a read only memory cell at the intersection of each ONO layer in the read only memory area;
a plurality of doping areas, each doping area optionally positioned in the substrate at a bottom of a read only memory cell to cause the read only memory cell with the doping area and a read only memory without the doping area to have at least two different threshold voltages, respectively, to present two different storage states;
a plurality of periphery circuit devices positioned on the substrate in the periphery area;
at least one inter-layer dielectric (ILD) and at least one patterned metal interconnect layer subsequently covering the nitride read only memory area, the read only memory area and the periphery area; and
a plurality of plugs positioned in the inter-layer dielectric for electrically connecting each device positioned in the nitride read only memory area, the read only memory area and the periphery area through the metal interconnect layer.

2. The system of claim 1 wherein the substrate is a silicon substrate.

3. The system of claim 1 wherein two pocket ion implantation areas of the first conductive type are disposed in the substrate at two sides of each bit line.

4. The system of claim 1 wherein the first conductive type is a P-type conductive type.

5. The system of claim 1 wherein a thickness of the ONO layer ranges from 100 to 250 angstroms (Å).

6. The system of claim 1 wherein the ONO layer is formed from a stacked structure comprising a bottom oxide layer with a thickness ranging from 20 to 150 angstroms, a silicon nitride layer with a thickness ranging from 20 to 150 angstroms, and a top oxide layer with a thickness ranging from 50 to 150 angstroms.

7. The system of claim 1 wherein each word line is composed of a polysilicon layer.

8. The system of claim 7 wherein a polysilicide layer is formed on a surface of the polysilicon layer.

9. The system of claim 1 wherein the read only memory is a mask read only memory (mask ROM, MROM).

10. The system of claim 1 wherein the plurality of doping areas are formed by utilizing an ion implantation process capable of optionally implanting ions into the substrate at a bottom of a read only memory cell to form ROM code.

11. A system on chip (SOC) characterized by nitride read only memory (NROM) and read only memory(ROM), the system comprising:
a substrate of a first conductive type, a nitride read only memory(NROM) area, a read only memory area and a periphery area defined on a surface of the substrate;
a plurality of ONO (oxide-nitride-oxide) layers positioned on the nitride read only memory area, the ONO layers disposed along a first direction;
a plurality of gate oxide layers positioned on the read only memory area, the gate oxide layers disposed along the first direction;
a plurality of conductive doping areas of a second conductive type positioned in the substrate between each ONO layer and each gate oxide layer, the conductive doping areas being used as bit lines of the system on chip;
an oxide layer positioned atop each bit line;
a plurality of word lines covering each ONO layer in the nitride read only memory area and the gate oxide layers in the read only memory area, the word lines disposed along a second direction and forming a nitride read only memory cell at the intersection of each ONO layer in the nitride read only memory area, and a read only memory cell at the intersection of each gate oxide layer in the read only memory area;
a plurality of doping areas, each doping area optionally positioned in the substrate at a bottom of a read only memory cell to cause the read only memory cell with the doping area and a read only memory without the doping area to have at least two different threshold voltages, respectively, to present two different storage states;
a plurality of periphery circuit devices positioned on the substrate in the periphery area;
at least one inter-layer dielectric (ILD) and at least one patterned metal interconnect layer subsequently covering the nitride read only memory area, the read only memory area, and the periphery area; and
a plurality of plugs positioned in the inter-layer dielectric for electrically connecting each device positioned in the nitride read only memory area, the read only memory area, and the periphery area through the metal interconnects layer.

12. The system of claim 11 wherein the substrate is a silicon substrate.

13. The system of claim 11 wherein two pocket ion implantation areas of the first conductive type are disposed in the substrate at two sides of each bit line.

14. The system of claim 11 wherein the first conductive type is a P-type conductive type.

15. The system of claim 11 wherein a thickness of the ONO layer ranges from 100 to 250 angstroms (Å).

16. The system of claim 11 wherein the ONO layer is formed from a stacked structure comprising a bottom oxide layer with a thickness ranging from 20 to 150 angstroms, a silicon nitride layer with a thickness ranging from 20 to 150 angstroms, and a top oxide layer with a thickness ranging from 50 to 150 angstroms.

17. The system of claim 11 wherein each word line is composed of a polysilicon layer.

18. The system of claim 17 wherein a polysilicide layer is formed on the surface of the polysilicon layer.

19. The system of claim 11 wherein the read only memory is a mask read only memory (mask ROM, MROM).

20. The system of claim 11 wherein the plurality of doping areas are formed by utilizing an ion implantation process that is capable of optionally implanting ions into the substrate at a bottom of a read only memory cell to form ROM code.
